(19) United States
(12) Patent Application Publication
(10) Pub. No.: US 2025/0260385 A1
(43) Pub. Date: Aug. 14, 2025

(54) ELECTRONIC FILTERING CIRCUIT

(71) Applicant: STMicroelectronics International N.V., Geneva (CH)

(72) Inventor: Mohamed BOUFNICHEL, MONNAIE (FR)

(21) Appl. No.: 19/035,487

(22) Filed: Jan. 23, 2025

(30) Foreign Application Priority Data
Feb. 8, 2024 (FR) FR2401259

(51) Int. Cl. H03H 9/54; H03H 9/17; H03H 9/52

(52) U.S. Cl. CPC H03H 9/542; H03H 9/174; H03H 9/52

(57) ABSTRACT

The present description concerns electronic filter circuit comprising an integrated passive device; a bulk acoustic wave filter stacked on the integrated passive device on the side of a first surface of the integrated passive device; and at least one conductive pillar crossing the integrated passive device and connecting an electrode of the bulk acoustic wave filter to a contacting element located on a second surface of the integrated passive device opposite to the first surface and intended to be connected to an external element.

### CROSS REFERENCE TO RELATED APPLICATIONS

This application is a translation of and claims the priority benefit of French patent application number 2401259, filed on Feb. 8, 2024, entitled “Circuit électronique de filtrage,” which is hereby incorporated by reference to the maximum extent allowable by law.

### TECHNICAL FIELD

The present disclosure generally concerns electronic devices, more particularly electronic filter circuits.

### BACKGROUND

Many electronic devices comprise at least one electronic filter circuit. Such circuits are, for example, integrated in cell phones, or smartphones, to avoid for the operation of a radio frequency communication receive channel of the phone to be disturbed by interference caused by radio frequency signals emitted by other electronic devices, or by noise originating from external radio frequency sources. Existing electronic filter circuits however suffer from various disadvantages.

### BRIEF SUMMARY

There exists a need to overcome all or part of the disadvantages of existing electronic filter circuits.

For this purpose, an embodiment provides an electronic filter circuit comprising an integrated passive device; a bulk acoustic wave filter stacked on the integrated passive device on the side of a first surface of the integrated passive device; and at least one conductive pillar crossing the integrated passive device and connecting an electrode of the bulk acoustic wave filter to a contacting element located on a second surface of the integrated passive device opposite to the first surface and intended to be connected to an external element.

According to an embodiment, the integrated passive device forms a cover for the bulk acoustic wave filter.

According to an embodiment, the first surface delimits, with a third surface of the bulk acoustic wave filter located in front of the first surface, a cavity.

According to an embodiment, the cavity has a thickness defined by a height of the at least one conductive pillar, the at least one conductive pillar protruding from the first surface.

According to an embodiment, the cavity is laterally delimited by a peripheral wall.

According to an embodiment, the peripheral wall is made of an insulating material, preferably a polymer material.

According to an embodiment, the at least one conductive pillar is located inside of the cavity.

According to an embodiment, the integrated passive device comprises a semiconductor substrate comprising a region inside and on top of which is formed at least one filter, preferably at least one bandpass filter, more preferably an RLC filter.

According to an embodiment, the bulk acoustic wave filter comprises a second semiconductor substrate comprising a region inside and on top of which is formed a bulk acoustic wave filter structure connected to the electrode.

An embodiment provides an electronic device, preferably a cell phone or smartphone, comprising a radio frequency integrated circuit comprising the electronic filter circuit as described.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a simplified and partial cross-section view of an example of an electronic filter circuit according to an embodiment;

FIG. 2A, FIG. 2B, FIG. 2C, FIG. 2D, and FIG. 2E each are a simplified and partial cross-section view of a structure obtained at the end of a step of a method of manufacturing an integrated passive device according to an embodiment;

FIG. 3A, FIG. 3B, and FIG. 3C each are a simplified and partial cross-section view of a structure obtained at the end of a step of a method of manufacturing an electronic filter circuit according to an embodiment; and

FIG. 4 is a simplified and partial top view of an example of a device integrating an electronic filter circuit.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, the applications of electronic filter circuits have not been detailed, the described embodiments being compatible with all or most applications of electronic filter circuits, subject to possible adaptations within the reach of those skilled in the art on reading of the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

In the following description, the terms “insulating” and “conductive” respectively signify, unless specified otherwise, electrically insulating and electrically conductive.

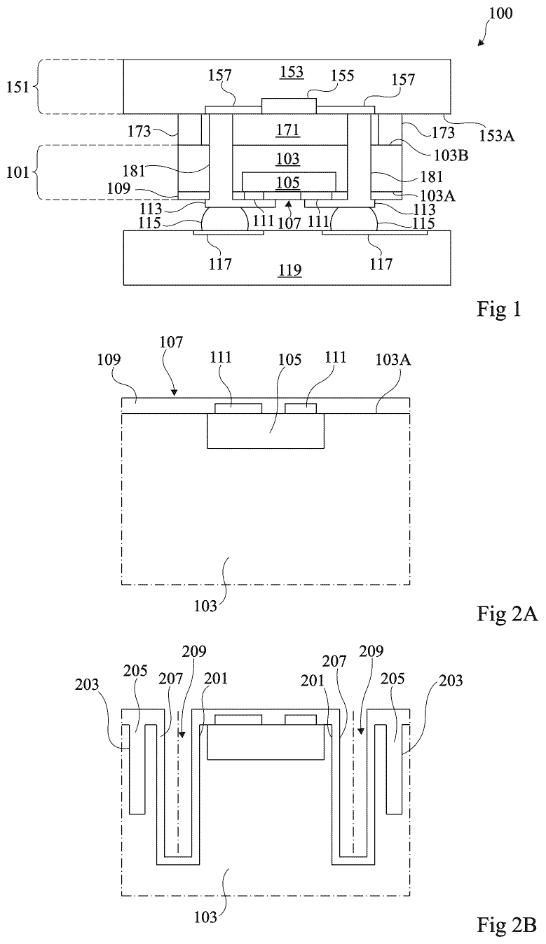

FIG. 1 is a partial and simplified cross-section view of an example of an electronic filter circuit 100 according to an embodiment.

In the shown example, electronic filter circuit 100 comprises a integrated passive device 101 comprising a semiconductor substrate 103, for example a piece of wafer made of a semiconductor material such as silicon. In this example, semiconductor substrate 103 comprises a region 105 flush with a surface 103A of semiconductor substrate 103 (the lower surface of substrate 103, in the orientation of FIG. 1) and having at least one bandpass filter formed therein, for example an integrated passive device (IPD) filter. Region 105 for example comprises a plurality of passive electronic components, for example each selected from among: a resistive component, for example a resistor; a capacitive component, for example a capacitor; and an inductive component, for example an inductor.

As an example, region 105 comprises an RLC filter comprising at least one resistive component, at least one capacitive component, and at least one inductive component. The structure of region 105 has not been detailed in FIG. 1 so as not to overload the drawing. In particular, the passive electronic components formed in region 105 of semiconductor substrate 103 have not been shown.

In the illustrated example, integrated passive device 101 further comprises an interconnection structure 107 coating surface 103A of semiconductor substrate 103. Interconnection structure 107 for example comprises a stack of insulating layers 109 and of conductive tracks 111 located inside of and/or between insulating layers 109, some of conductive tracks 111 being in contact with region 105.

In the shown example, each conductive track 111 is connected to a contacting element 113 located on surface 103A of semiconductor substrate 103. Conductive tracks 111 for example enable to connect contacting elements 113 to terminals of passive electronic components formed in region 105. Contacting elements 113 are for example intended to be connected to elements external to circuit 100. In the illustrated example, contacting elements 113 are each connected, by a solder ball 115, to a contacting element 117 supported by a support substrate 119. As an example, support substrate 119 is a printed circuit board. Each contacting element 117 is for example a conductive pad or a conductive track.

In the shown example, circuit 100 further comprises a bulk acoustic wave (BAW) filter 151 stacked on integrated passive device 101 on the side of a surface 103B of semiconductor substrate 103 opposite to its surface 103A (on the upper surface side of substrate 103, in the orientation of FIG. 1). In the shown example, bulk acoustic wave filter 151 comprises a semiconductor substrate 153, for example a piece of wafer made of a semiconductor material such as silicon, having a bulk acoustic wave filter structure 155 connected to electrodes 157 formed inside and on top of it.

Structure 155 is for example of FBAR (thin-film bulk acoustic resonator) type, also called “membrane” bulk acoustic wave filter. In this case, structure 155 comprises, for example, a membrane made of an insulating material suspended above an air-filled cavity formed in substrate 153 and at least one piezoelectric layer located on the membrane, for example interposed between electrodes 157. Structure 155 has not been detailed in FIG. 1 to avoid overloading the drawing. Alternatively, structure 155 may be of SMR (solidly mounted resonator) type. In this case, structure 155 comprises, for example, a membrane of insulating material located on and in contact with a Bragg mirror, and at least one piezoelectric layer located on the membrane, for example interposed between electrodes 157.

In the illustrated example, integrated passive device 101 is separated from bulk acoustic wave filter 151 by a cavity 171. In this example, cavity 171 extends vertically from surface 103B of semiconductor substrate 103 (that is, from the upper surface of integrated passive device 101, in the orientation of FIG. 1) to a surface 153A of the semiconductor substrate 153 of bulk acoustic wave filter 151 located in front of surface 103B (that is, all the way to the lower surface of bulk acoustic wave filter 151, in the orientation of FIG. 1). In the shown example, cavity 171 is laterally delimited, or laterally bordered, by a peripheral wall 173. In the example illustrated in FIG. 1, peripheral wall 173 extends vertically from surface 103B of substrate 103 all the way to surface 153A of substrate 153. As an example, peripheral wall 173 is made of an insulating material, such as a polymer. The cavity 171 defined by wall 173 and surfaces 103B and 153A is for example filled with air. As a variant, the inside of cavity 171 may be placed under partial vacuum.

In the shown example, circuit 100 further comprises conductive pillars 181 crossing integrated passive device 101 and each connecting one of the electrodes 157 of bulk acoustic wave filter 151 to one of contacting elements 113. In the illustrated example, each conductive pillar 181 protrudes from surface 103B of semiconductor substrate 103, crosses cavity 171, and is located on top of and in contact with one of electrodes 157. As an example, the height of each pillar 181 defines the height, or thickness, of cavity 171.

Peripheral wall 173 for example has, in top view,

a ring shape surrounding conductive pillars 181. This advantageously enables to protect conductive pillars 181 from external stress, such as mechanical impacts. This further enables to decrease the lateral dimensions of the electronic filter circuit, for example as compared with a structure where the electrodes 157 of BAW filter 151 would be connected to the contacting elements 117 of support substrate 119 by pillars located outside of cavity 171. As an example, peripheral wall 173 has, in top view, a periphery of any shape, for example substantially rectangular, oval, square, circular, etc. Cavity 171 is for example tight or sealed. This prevents particles or moisture from entering cavity 171. As a variant, peripheral wall 173 may have openings especially allowing air exchanges between the inside of cavity 171 and the outside environment. This for example favors a pressure balance between the inside and the outside of cavity 171, for example so as to take into account a heating of circuit 100 during its operation.

In circuit 100, integrated passive device 101 is advantageously used as the cover of bulk acoustic wave filter 151. This advantageously enables to avoid the use of a dedicated cover comprising no electronic component. In other words, the use of integrated passive device 101 as a cover for bulk acoustic wave filter 151 enables to combine, in a same element, a mechanical protection function, provided in particular by substrate 103 and peripheral wall 173, and a filtering function, implemented in particular by region 105.

FIG. 1 illustrates an example where circuit 100 comprises two conductive pillars 181, each connecting one of the contacting elements 113 of integrated passive device 101 to one of the electrodes 157 of bulk acoustic wave filter 151. This example is however not limiting, and the circuit 100 may more generally comprise an integer number, greater than or equal to one, of conductive pillars, each connecting a contacting element of integrated passive device 101 to an electrode of bulk acoustic wave filter 151.

Filters using an integrated passive device advantageously have, in attenuation bands located on either side of their passband, a high rejection performance. However, these filters have the disadvantage of having, interposed between their passband and each of their attenuation bands, wide transition bands. Conversely, bulk acoustic wave filters have the advantage of having transition bands narrower than those of filters using an integrated passive device, but suffer from a lower rejection performance. The fact of combining, in circuit 100, integrated passive device 101 and bulk acoustic wave filter 151 enables to associate the advantages and to eliminate, or to decrease, the disadvantages of these two types O 41 filters. Circuit 100 for example has a transition band narrower than that of integrated passive device 101 taken alone, and a better rejection performance than bulk acoustic wave filter 151 taken alone.

Further, since integrated passive device 101 and the bulk acoustic wave filter 151 of circuit 100 are stacked, a space saving advantageously results therefrom. This further enables to provide shorter connections, thus and lower resistances, between integrated passive device 101 and bulk acoustic wave filter 151.

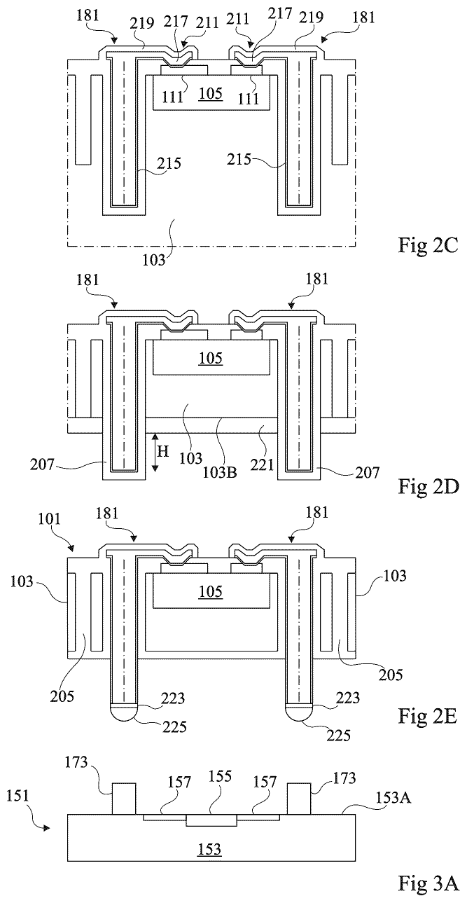

FIG. 2A, FIG. 2B, FIG. 2C, FIG. 2D, and FIG. 2E each are a simplified and partial cross-section view of a structure obtained at the end of a step of a method of manufacturing integrated passive device 101 according to an embodiment.

FIG. 2A shows the structure obtained after the forming of region 105 and the forming of interconnection structure 107 on surface 103A of substrate 103. One or a plurality of electronic components, not shown, are formed inside and/or on top of region 105. According to an embodiment, at this stage of the process, substrate 103 corresponds to a wafer, and the regions 105 of a plurality of integrated passive devices are formed inside and/or on top of substrate 103, which regions 105 may be identical or different. In FIG. 2A, a single region 105 is shown and interconnection structure 107 comprises conductive tracks 111 connected to region 105 and insulating layer 109 covering conductive tracks 111 and surface 103A of substrate 103 around conductive tracks 111. At this stage of the method, the thickness of substrate 103 is greater than the desired final thickness of substrate 103. The thickness of substrate 103 at this stage of the method is, for example, in the range from 500 μm to 1.3 mm.

FIG. 2B shows the structure obtained after the forming of an opening 201 at the desired location of each connection pillar 181 and the forming of an opening 203 at the desired location of insulating walls 205. Openings 201 and 203 thoroughly cross interconnection structure 107 and extend over part of the thickness of substrate 103, from surface 103A. Openings 201 have the same depth and openings 203 have the same depth. The depth of openings 201 is greater than the depth of openings 203. The depth of openings 203 is, for example, substantially equal to the desired final thickness of substrate 103. The depth of openings 203 is, for example, in the range from 50 to 300 μm. Openings 201 and 203 are for example formed by steps of deep reactive ion etching (DRIE). According to the method used for the forming of openings 201 and 203, openings 201 and 203 may be formed simultaneously or may be formed in separate steps. In particular, with a deep reactive ion etching, the etching speed depends on the diameter of the opening, so that openings 203, which for example have a width smaller than the average diameter of openings 201, may be formed simultaneously to openings 201.

Each opening 201 may have a cross-section having any shape. As an example, each opening 201 has, in top view, a substantially circular shape, a rectangular shape with rounded corners, an oval shape, etc. Openings 201 for example have a depth depending on the desired height of pillars 181.

FIG. 2B further shows the structure obtained after the forming of an insulating layer 207 in each opening 201 and the forming of insulating wall 205 in each opening 203. At this stage of the method, insulating layer 207 coats the side walls and the bottom of opening 201. This step may comprise the deposition of an insulating layer simultaneously on the walls of opening 203 and on the walls of opening 201, the thickness of the insulating layer being such that it fills up, that is, totally fills, opening 203 but does not fill up each opening 201 so that a cavity 209 is present in each opening 201 after the forming of the insulating layer.

FIG. 2C shows the structure obtained after the forming, for each connection pillar to be formed, of an opening 211 in insulating layer 109 to expose one of conductive tracks 111, the deposition of a mask (not shown) on insulating layer 207 comprising, for each connection pillar to be formed, an opening exposing cavity 209, opening 211, and the portion of insulating layer 109 coupling cavity 209 to opening 211, and the forming of an interface layer 215 in each opening. At this stage of the method, interface layer 215 covers all the walls of cavity 209, in particular the side walls and bottom of cavity 209, the walls of opening 211, and the exposed portion of insulating layer 109 coupling cavity 209 to the corresponding opening 211. The mask may correspond to a film which is applied to insulating layer 109.

FIG. 2C further shows the structure obtained after, for each connection pillar to be formed, a complete filling of each cavity 209 with a conductive material, thus forming a shaft of connection pillar 181, and the forming of a connection portion 217 of each connection pillar. Connection portion 217 corresponds, for example, to one of the contacting elements 113 of circuit 100. The conductive material forming the shaft may be deposited by electrodeposition on interface layer 215. In this case, the deposition of the conductive material is performed from interface layer 215 in a direction substantially perpendicular to interface layer 215. This advantageously enables to fill cavity 209 even if the form factor of cavity 209, that is, the ratio of the cavity height to the cavity diameter, is high, since the deposition of the conductive material is performed in particular from the side walls of cavity 209.

FIG. 2C further shows the structure obtained after removal of the film and the forming, for each connection pillar 181, of an insulating layer 219 covering connection portion 217.

FIG. 2D shows the structure obtained after an etching of substrate 103 from its surface 103B. At the end of the etch step, for each connection pillar 181, a portion of the shaft, surrounded by interface layer 215 and insulating layer 207, projects from substrate 103, from surface 103B, along a height H. Height H corresponds, for example, substantially to the thickness of the future cavity 171. The etch step may involve a chemical selective forming etching over the material insulating layer 207. The etching of substrate 103 is for example stopped when the end of the wall is flush with lower surface 103B. Height H is determined by the etch step.

FIG. 2D further shows the structure obtained after the forming of an insulating layer 221 on surface 103B of substrate 103. Insulating layer 221 is for example made of the same material as insulating layer 207 and the thickness of insulating layer 221 is for example, at this stage of the method, substantially equal to the sum of the thickness of insulating layer 207 and of the desired final thickness of insulating layer 221, for example equal to twice the thickness of insulating layer 207.

FIG. 2E shows the structure obtained after the full etching of the portion of insulating layer 207 which is exposed on the side of surface 103B of substrate 103. This step may further cause the etching of insulating layer 221 across the thickness of insulating layer 207. The insulating layer 221 having the desired final thickness is then obtained.

FIG. 2E further shows the structure obtained after, for each connection pillar 181, the etching of the interface layer 215 covering the end surface, the forming of a top coat layer 223, and the forming of a block of bonding material 225.

FIG. 2E also shows the structure obtained after a cutting step to separate integrated passive devices 101. As an example, the cutting lines are located between the walls 205 of adjacent integrated passive devices 101.

Each integrated passive device 101 thus individualized may then be bonded to an external element, for example support substrate 119. Wall 205 protects region 105 of integrated passive device 101 in particular against electrostatic discharges at the side walls of integrated passive device 101 during the handling and the bonding of integrated passive device 101 to the external element.

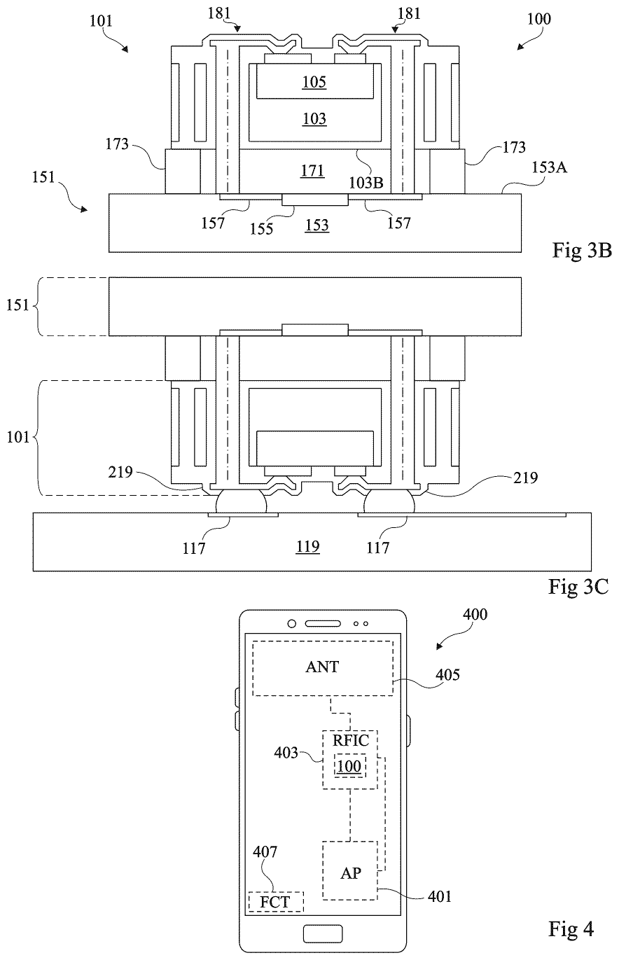

FIG. 3A, FIG. 3B, and FIG. 3C each are a simplified and partial cross-sectional view of a structure obtained at the end of a step of a method of manufacturing an electronic filter circuit, for example the circuit 100 of FIG. 1, according to an embodiment. The steps described hereafter in relation with FIGS. 3A to 3C may indifferently be implemented before, during, or after the steps of forming of integrated passive device 101 previously described in relation with FIGS. 2A to 2E.

FIG. 3A shows the structure obtained after the forming of structure 155 inside and on top of semiconductor substrate 153, and after the forming of electrodes 157.

FIG. 3A further shows the structure obtained after the forming of peripheral wall 173 on surface 153A of semiconductor substrate 153. At the end of this step, peripheral wall 173 has, for example, a height substantially equal to the height H of pillars 181.

FIG. 3B shows the structure obtained after the transfer of the integrated passive device 101 of FIG. 2E onto the bulk acoustic wave filter 151 of FIG. 3A. As an example, integrated passive device 101 is turned upside down with respect to the orientation of FIG. 2E, so that surface 103B of semiconductor substrate 103 is located in front of surface 153A of bulk acoustic wave filter 151. The blocks of bonding material 225 of integrated passive device 101 are then for example brought into contact with the electrodes 157 of bulk acoustic wave filter 151, peripheral wall 173 bearing on surface 103B of semiconductor substrate 103. Electronic filter circuit 100 is for example thus obtained.

FIG. 3C shows the structure obtained after the bonding of electronic filter circuit 100 to support substrate 119. As an example, insulating layer 219 is previously opened vertically in line with contacting elements 113 to clear their surface opposite to pillars 181. Circuit 100 is then for example transferred onto support substrate 119 so that surface 103A of semiconductor substrate 103 is located in front of the contacting elements 117 of support substrate 119.

FIG. 4 is a simplified and partial top view of an example of a device 400 integrating an electronic filter circuit, for example circuit 100. In the shown example, device 400 is a cell phone, or smartphone.

In this example, device 400 comprises a processing circuit 401 (AP), for example a microcontroller or a main microprocessor of device 400. Processing circuit 401 is for example connected to a radio frequency integrated circuit 403 (RFIC) comprising electronic filter circuit 100. In the illustrated example, radio frequency integrated circuit 403 is connected to an antenna 405 (ANT), for example a radio frequency communication antenna of device 400. Although this has not been detailed in FIG. 4 to avoid overloading the drawing, radio frequency integrated circuit 403 may further comprise components and circuits intended to implement functions of impedance matching, amplification, modulation/demodulation, switching, etc.

Device 400 may further comprise other elements, for example other electronic components or circuits, not shown in FIG. 4. These elements have been symbolized, in FIG. 4, by a functional block 407 (FCT).

Various embodiments and variants have been described. Those skilled in the art will understand that certain features of these various embodiments and variants may be combined, and other variants will occur to those skilled in the art. In particular, those skilled in the art are capable, based on the indications of the present description, to provide and manufacture a circuit similar to circuit 100 but comprising a plurality of integrated passive devices 101 stacked on one another.

Furthermore, although FIG. 4 takes as an example the case of integrating circuit 100 into a cell phone or smartphone, the embodiments described are not limited to this example but apply more generally to any device or system with wireless communications functions, for example in the field of telematics. In particular, circuit 100 can be integrated into motor vehicles, for example to implement wireless Internet access functionalities, vehicle communication with external equipment or systems, autonomous driving, etc.

Finally, the practical implementation of the described embodiments and variants is within the abilities of those skilled in the art based on the functional indications given hereabove. In particular, the described embodiments are not limited to the specific examples of materials and of dimensions mentioned in the present description.

1. An electronic filter circuit comprising:
an integrated passive device;
a bulk acoustic wave filter stacked on the integrated passive device on the side of a first surface of the integrated passive device; and
at least one conductive pillar crossing the integrated passive device and connecting an electrode of the bulk acoustic wave filter to a contacting element located on a second surface of the integrated passive device opposite to the first surface and intended to be connected to an external element.

2. The circuit according to claim 1, wherein the integrated passive device forms a cover for the bulk acoustic wave filter.

3. The circuit according to claim 1, wherein the first surface delimits, with a third surface of the bulk acoustic wave filter located in front of the first surface, a cavity.

4. The circuit according to claim 3, wherein the cavity has a thickness defined by a height of the at least one conductive pillar, the at least one conductive pillar protruding from the first surface.

5. The circuit according to claim 3, wherein the cavity is laterally delimited by a peripheral wall.

6. The circuit according to claim 5, wherein the peripheral wall is made of an insulating material.

7. The circuit according to claim 3, wherein the at least one conductive pillar is located inside of the cavity.

8. The circuit according to claim 1, wherein the integrated passive device comprises a first semiconductor substrate comprising a region inside and on top of which is formed at least one filter.

9. The circuit according to claim 1, wherein the bulk acoustic wave filter comprises a second semiconductor substrate comprising a region inside and on top of which is formed a bulk acoustic wave filter structure connected to the electrode.

10. An electronic device comprising:
an electronic filter circuit comprising:
an integrated passive device;
a bulk acoustic wave filter stacked on the integrated passive device on the side of a first surface of the integrated passive device; and
at least one conductive pillar crossing the integrated passive device and connecting an electrode of the bulk acoustic wave filter to a contacting element located on a second surface of the integrated passive device opposite to the first surface and intended to be connected to an external element.

11. The electronic device according to claim 10, wherein the integrated passive device forms a cover for the bulk acoustic wave filter.

12. The electronic device according to claim 10, wherein the first surface delimits, with a third surface of the bulk acoustic wave filter located in front of the first surface, a cavity.

13. The electronic device according to claim 12, wherein the cavity has a thickness defined by a height of the at least one conductive pillar, the at least one conductive pillar protruding from the first surface.

14. The electronic device according to claim 12, wherein the cavity is laterally delimited by a peripheral wall.

15. The electronic device according to claim 14, wherein the peripheral wall is made of an insulating material.

16. The electronic device according to claim 12, wherein the at least one conductive pillar is located inside of the cavity.

17. The electronic device according to claim 10, wherein the integrated passive device comprises a first semiconductor substrate comprising a region inside and on top of which is formed at least one filter.

18. The electronic device according to claim 10, wherein the bulk acoustic wave filter comprises a second semiconductor substrate comprising a region inside and on top of which is formed a bulk acoustic wave filter structure connected to the electrode.

19. The electronic device of claim 10, wherein the electronic device is a cellular telephone.
